(19) United States
(12) Patent Application Publication
(10) Pub. No.: US 2011/0265724 A1
(43) Pub. Date: Nov. 3, 2011

(54) METAL-ORGANIC CHEMICAL VAPOR DEPOSITION APPARATUS

(75) Inventor: Chun-Te CHIANG, Tainan City (TW)

(73) Assignee: CHI MEI LIGHTING TECHNOLOGY CORP., Tainan City (TW)

(21) Appl. No.: 13/095,917

(22) Filed: Apr. 28, 2011

(30) Foreign Application Priority Data
Apr. 29, 2010 (TW) 99113735

(51) Int. Cl. C23C 16/458; C23C 16/46; C23C 16/455

(52) U.S. Cl. 118/725

(57) ABSTRACT

A metal-organic chemical vapor deposition (MOCVD) apparatus is described. The MOCVD apparatus includes a reaction chamber, a rotation stand, a wafer susceptor, a heater and a shower head. The reaction chamber includes an opening. The rotation stand is disposed within the reaction chamber. The wafer susceptor is disposed on the rotation stand, and the wafer susceptor rotates by rotating of the rotation stand. The wafer susceptor includes a plurality of wafer pockets of at least two different diameters disposed on a surface of the wafer susceptor and the wafer pockets are suitable to correspondingly carry a plurality of wafers. The heater is disposed under the wafer susceptor and within the rotation stand. The shower head covers the opening of the reaction chamber and applies a gaseous precursor toward the surface of the wafer susceptor.

### RELATED APPLICATIONS

This application claims priority to Taiwan Application Serial Number 099113735, filed Apr. 29, 2010, which is herein incorporated by reference.

### FIELD OF THE INVENTION

The present invention relates to a chemical vapor deposition (CVD) apparatus, and more particularly, to a metal-organic CVD (MOCVD) apparatus.

### BACKGROUND OF THE INVENTION

In a process of fabricating a light-emitting diode (LED), the quality of semiconductor material layers of the LED is closely related with the luminous quality of the LED, so that an epitaxy procedure of each semiconductor material layer is a very important step. In the epitaxy procedure of the LED, a wafer susceptor is typically needed to carry wafers.

Typically, in the current wafer susceptor technology, a single wafer susceptor only can be used to carry wafers of the same size. In the current epitaxy process of the LED, the design of the wafer susceptor is to distribute wafer pockets having a diameter of 2 inches on the entire wafer susceptor. Due to small size of the wafer pockets, the utilization ratio of the wafer susceptor can be higher by closely arranging the wafer pockets.

As the process technology is improved, the wafer size is gradually increased. For example, in the fabrication of a LED, the size of a blue light epitaxial substrate is developed from original 2 inches to current 4 inches. The general purpose of increasing the substrate size is to reduce the cost of the subsequence chip process. However, the size of the wafer susceptor should match the original reaction chamber, therefore is limited and cannot be enlarged. After the wafer pockets of the wafer susceptor are redrawn for packing wafers having a diameter of 4 inches, the amount of the wafer pockets having a diameter of 4 inches on the wafer susceptor is greatly reduced to seven.

Refer to FIG. 1. FIG. 1 is a schematic diagram showing layouts of wafer pockets of two different sizes on a conventional wafer susceptor. If a wafer susceptor 100 is designed to carry wafers having a diameter of 2 inches, thirty-one wafer pockets 104 having a diameter of 2 inches as indicated by dotted circles in FIG. 1 can be disposed on a surface 102 of the wafer susceptor 100. With the design, the small wafer pockets 104 can be arranged closely. However, when the wafer susceptor 100 is designed to carry wafers having a diameter of 4 inches, only seven wafer pockets 106 as indicated by continuous circles in FIG. 1 can be disposed on the surface 102 of the wafer susceptor 100 due to the limit of the wafer size.

From FIG. 1, it is known that the area utilization ratio of the surface 102 of the wafer susceptor 100 set with wafer pockets 106 having the diameter of 4 inches is obviously less than that of the surface 102 of the wafer susceptor 100 set with wafer pockets 104 having the diameter of 2 inches. Therefore, in reaction chambers of the same size in MOCVD apparatuses, although the use of large wafers can reduce the cost of the subsequence chip process, the purpose of increasing the throughput of the devices cannot be achieved in the front end of the epitaxy process, and the throughput of the devices is decreased, thereby increasing the process cost.

### SUMMARY OF THE INVENTION

Therefore, one aspect of the present invention is to provide a MOCVD apparatus, in which a wafer susceptor is set with wafer pockets of various sizes, so that the use space of the wafer susceptor can be utilized more effectively.

Another aspect of the present invention is to provide a MOCVD apparatus, in which a wafer susceptor has a large carrying space, so that the production efficiency of devices is greatly increased, and the throughput is enhanced.

Still another aspect of the present invention is to provide a MOCVD apparatus, which can give consideration to the space utilization ratio of a wafer susceptor and the use of large wafers, so that the production cost is reduced.

According to the aforementioned aspects, the present invention provides a MOCVD apparatus. The MOCVD apparatus includes a reaction chamber, a rotation stand, a wafer susceptor, a heater and a shower head. The reaction chamber includes an opening. The rotation stand is disposed within the reaction chamber. The wafer susceptor is disposed on the rotation stand, and the wafer susceptor rotates by rotating of the rotation stand. The wafer susceptor includes a plurality of wafer pockets of at least two different diameters disposed on a surface of the wafer susceptor, and the wafer pockets are suitable to correspondingly carry a plurality of wafers. The heater is disposed under the wafer susceptor and within the rotation stand. The shower head covers the opening of the reaction chamber and applies a gaseous precursor toward the surface of the wafer susceptor.

According to a preferred embodiment of the present invention, the wafer pockets includes a plurality of first wafer pockets having a same diameter and a plurality of second wafer pockets having a same diameter, and the diameter of the first wafer pockets is longer than the diameter of the second wafer pockets.

According to another preferred embodiment of the present invention, a depth of the first wafer pockets is larger than a depth of the second wafer pockets.

According to still another preferred embodiment of the present invention, a depth of the first wafer pockets is the same as a depth of the second wafer pockets.

According to yet another preferred embodiment of the present invention, a depth of each of the wafer pockets is less than a thickness of the corresponding wafer.

By disposing wafer pockets of at least two sizes on a wafer susceptor, the use space of the wafer susceptor can be utilized more effectively. Therefore, the invention can give consideration to the space utilization ratio of the wafer susceptor and the use of large wafers, so that the production efficiency of the devices is enhanced and the production cost is reduced.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 is a schematic diagram showing layouts of wafer pockets of two sizes on a conventional wafer susceptor;

FIG. 2 is a schematic diagram showing a MOCVD apparatus in accordance with a preferred embodiment of the present invention;

FIG. 3 illustrates a top view of a wafer susceptor in accordance with a preferred embodiment of the present invention;

FIG. 4 illustrates a cross-sectional view of a wafer susceptor in accordance with a preferred embodiment of the present invention; and

FIG. 5 illustrates a top view of a wafer susceptor in accordance with another preferred embodiment of the present invention.

### DETAILED DESCRIPTION OF THE PREFERRED EMBODIMENT

Refer to FIG. 2. FIG. 2 is a schematic diagram showing a MOCVD apparatus in accordance with a preferred embodiment of the present invention. In the present embodiment, a MOCVD apparatus 200 is suitable to perform epitaxy operations of semiconductor material layers of LEDs. The MOCVD apparatus 200 may include a reaction chamber 202, a rotation stand 204, a wafer susceptor 206, a heater 218 and a shower head 220, for example.

In the MOCVD apparatus 200, the reaction chamber 202 typically has an opening 226, so that a plurality of wafers can be disposed on the wafer susceptor 206 through the opening 226. According to the process requirement, the reaction chamber 202 may be selectively set with at least one exhaust pipe 222. The exhaust pipe 222 is usually disposed in the lower part of the reaction chamber 202 for exhausting the waste gas formed in the process. The epitaxy operations of the devices, such as LEDs, are usually performed within the reaction chamber 202.

The rotation stand 204 is disposed within the reaction chamber 202. According to the process requirements, the rotation stand 204 can spin around within the reaction chamber 202 to further drive wafers 210 and 214 thereon to rotate. The rotation stand 204 may be composed of a hollow cylinder or a crutch structure for example.

The wafer susceptor 206 is used to support and carry a plurality of wafers 210 and 214, so as to convey the wafers 210 and 214 for processing. The wafer susceptor 206 is disposed on the rotation stand 204 and is supported by the rotation stand 204. The wafer susceptor 206 may be fixed on the rotation stand 204 by a wedge fastening method. While the rotation stand 204 is rotating, the wafer susceptor 206 fixed on the rotation stand 204 will rotate, so that the wafers 210 and 214 on the wafer susceptor 206 will rotate.

When an epitaxy process is performed within the MOCVD apparatus 200, an epitaxy product formed by a chemical reaction within the given reaction chamber 202 is deposited on the entire surface of the wafer susceptor 206. Thus, the epitaxy layers deposited on gaps between the wafers cannot be used in the following process, thereby causing a waste. Therefore, while the amount of devices that can be treated in the same reaction chamber space is larger, the manufacturing cost of each device is reduced. Accordingly, the design of the wafer susceptor 206 has influence on the throughput of the devices.

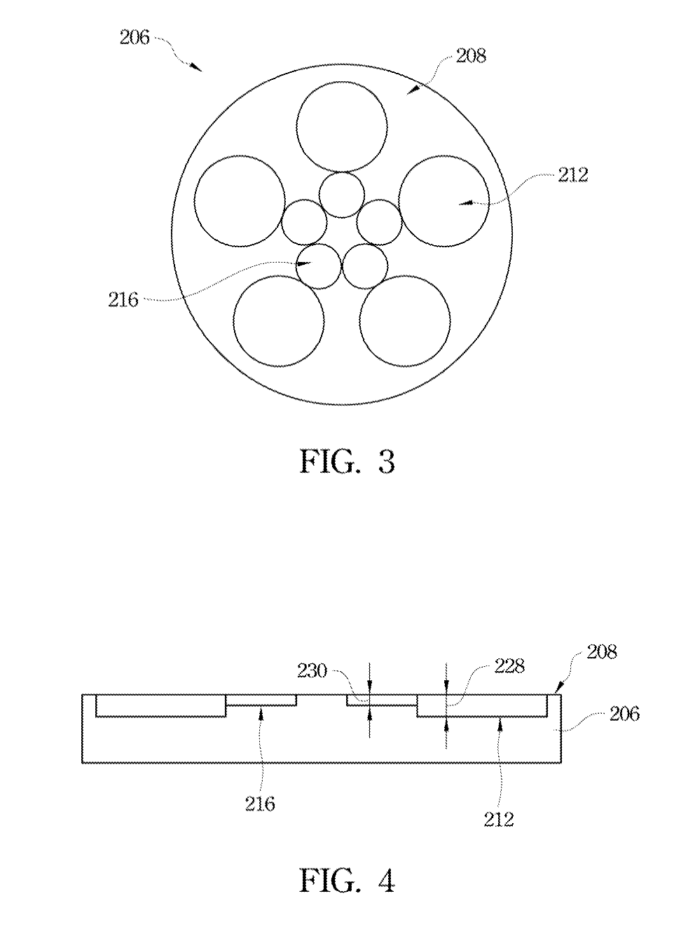

Simultaneously refer to FIG. 3 and FIG. 4. FIG. 3 illustrates a top view of a wafer susceptor in accordance with a preferred embodiment of the present invention, and FIG. 4 illustrates a cross-sectional view of the wafer susceptor illustrated in FIG. 3. In the present embodiment, a surface 208 of the wafer susceptor 206 is set with a plurality of wafer pockets 212 and 216. The wafer pockets 212 and 126 are concavities indented in the surface 208 of the wafer susceptor 206. Therefore, the wafers 210 and 214 can be firmly held by the wafer susceptor 206 for being processed within the reaction chamber 202.

As shown in the embodiment illustrated in FIG. 3, the wafer pocket 212 and 216 are all circle-shaped. Furthermore, in the embodiment, the wafer susceptor 206 includes wafer pockets 212 and 216 of two different diameters. Diameters of all wafer pockets 212 are the same, diameters of all wafer pockets 216 are the same, and the diameter of the wafer pocket 212 is longer than the diameter of the wafer pocket 216. In one example, in a process of a LED, the diameter of the wafer pocket 212 may be 4 inches, and the diameter of the wafer pocket 216 may be 2 inches, for example.

In the present embodiment, the larger wafer pockets 212 may be firstly formed on the surface 208 of the wafer susceptor 206, and the smaller wafer pockets 216 are then formed on the unoccupied region of the surface 208 of the wafer susceptor 206. Therefore, the utilization ratio of the surface 208 of the wafer susceptor 206 is increased, thereby enhancing the production efficiency of the device.

It is worthy of note that, although the wafer susceptor 206 of the present embodiment includes wafer pockets 212 and 216 of two different diameters, the wafer susceptor may include wafer pockets of more than two different diameters in other embodiments.

Referring to FIG. 2 again, in the wafer susceptor 206, the wafer pockets 212 and 216 of the different diameters are suitable to carry the wafers 210 and 214 of the different sizes respectively. The diameters of the wafer pockets 212 and 216 may be equal to or longer than the diameter of the corresponding wafers 210 and 214 for carrying the wafers 210 and 214. Shapes of the wafer pockets 212 and 216 may be the same as shapes of the corresponding wafers 210 and 214. In other embodiments, the shapes of the wafer pockets 212 and 216 may be different from the shapes of the corresponding wafers 210 and 214.

Referring to FIG. 2 and FIG. 4, in one embodiment, depths 228 and 230 of the wafer pockets 212 and 216 are preferably less than or equal to thicknesses of the corresponding wafers 210 and 214. Therefore, when the wafers 210 and 214 are respectively loaded in the wafer pockets 212 and 216 of the wafer susceptor 206, top surfaces of the wafers 210 and 214 may be level with the surface 208 of the wafer susceptor 206, or may be slightly higher than the surface 208 of the wafer susceptor 206. Accordingly, when a deposition step, such as an epitaxy step, is performed on the wafers 210 and 214 on the wafer susceptor 206, it can prevent materials from depositing and covering sidewalls of the wafer pockets 212 and 216 on the wafer susceptor 206, thereby can prevent the deposited materials on the sidewalls of the wafer pockets 212 and 216 from obstructing the subsequent process.

The wafers of the different sizes have different thicknesses, so that the wafer pockets 212 and 216 of the wafer susceptor 206 can be designed to have different depths to match the thicknesses of the wafers. Typically, the thickness of the larger wafer 210 is larger than the thickness of the smaller wafer 214. Therefore, in one embodiment, as shown in FIG. 4, the depth 228 of the wafer pocket 212 for carrying the larger wafer 210 is larger than the depth 230 of the wafer pocket 216 for carrying the smaller wafer 214. However, in other embodiments, the wafer pocket for carrying the larger wafer also can be designed to have a depth the same as that of the wafer pocket for carrying the smaller wafer.

Referring to FIG. 2 again, the heater 218 is disposed under the wafer susceptor 206 and within the rotation stand 204 to heat the wafers 210 and 214 on the wafer susceptor 206. The operation of the heater 218 is preferably independent of that of the rotation stand 204, so that the heater 218 will not rotate while the rotation stand 204 is rotating. The wafers 210 and 214 on the wafer susceptor 206 can be uniformly heated by the rotation of the wafer susceptor 206 driven by the rotation of the rotation stand 204, so that the properties of the fabricated devices are more consistent.

The shower head 220 is disposed on the reaction chamber 202 and covers the opening 226 of the reaction chamber 202. A lower surface of the shower head 220 includes a plurality of nozzles 221 facing the wafers 210 and 214 on the wafer susceptor 206. Therefore, the gaseous precursor 224 flowing into the shower head 220 can be applied to the wafers 210 and 214 on the surface 208 of the wafer susceptor 206 through the nozzles 221, so that a deposition step, such as an epitaxy step, can be performed on the wafers 210 and 214.

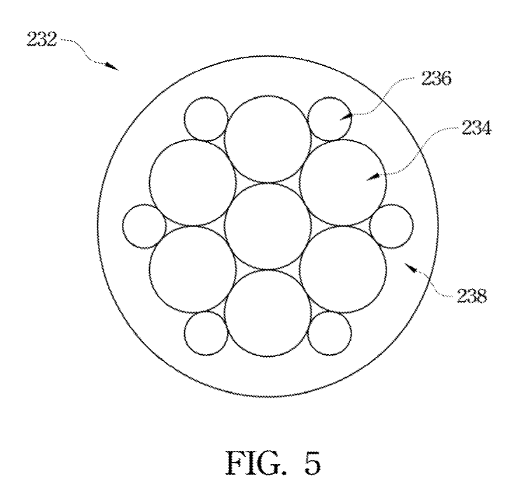

Refer to FIG. 5. FIG. 5 illustrates a top view of a wafer susceptor in accordance with another preferred embodiment of the present invention. In the present embodiment, seven larger wafer pockets 234 may be firstly disposed on a surface 238 of a wafer susceptor 232, and six smaller wafer pockets 236 may be then disposed outside the larger wafer pockets 234.

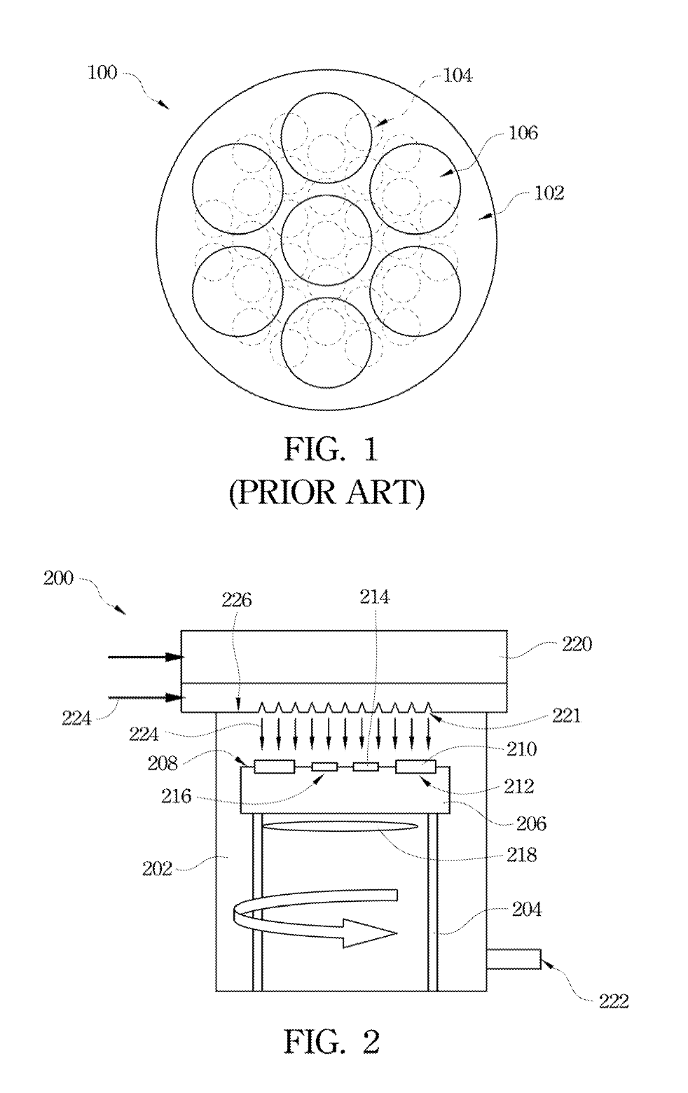

For example, the wafer susceptor 100 shown in FIG. 1, each of the wafer susceptor 206 shown in FIG. 3 and the wafer susceptor 232 shown in FIG. 5 is a wafer susceptor having a diameter of 380 mm. With such a diameter, the conventional wafer susceptor 100 is designed to carry thirty-one pieces of wafers having a diameter of 2 inches. In the current reaction chamber, when the wafer susceptor 100 is used to carry thirty-one pieces of the wafers having the diameter of 2 inches, one single epitaxy procedure can produce 433318 pieces of LED chips of a small size (10*23 mil²), or 125674 pieces of LED chips of a medium-large size (20*40 mil²). When the wafer susceptor 100 is used to carry seven pieces of wafers having a diameter of 4 inches, one single epitaxy procedure can produce 391391 pieces of LED chips of a small size (10*23 mil²), or 113505 pieces of LED chips of a medium-large size (20*40 mil²). From thirty-one pieces of the wafers having the diameter of 2 inches to seven pieces of the wafers having the diameter of 4 inches, the throughput of the small LED chips is decreased by a ratio of about 10.72%, and the throughput of the medium-large LED chips is decreased by a ratio of about 10.71%.

In addition, when the wafer susceptor 206 shown in FIG. 3 is used, one single epitaxy procedure can produce 405368 pieces of LED chips of a small size (10*23 mil²), or 117560 pieces of LED chips of a medium-large size (20*40 mil²). In comparison with the wafer susceptor used to carrying thirty-one pieces of the wafers having the diameter of 2 inches, the throughput of the small LED chips is decreased by a ratio of about 6.89%, and the throughput of the medium-large LED chips is decreased by a ratio of about 6.9%. However, in comparison with the wafer susceptor used to carrying seven pieces of the wafers having the diameter of 4 inches, the throughput of the small LED chips is increased by a ratio of about 3.57%, and the throughput of the medium-large LED chips is increased by a ratio of about 3.57%.

Furthermore, when the wafer susceptor 232 shown in FIG. 5 is used, one single epitaxy procedure can produce 475259 pieces of LED chips of a small size (10*23 mil²), or 137829 pieces of LED chips of a medium-large size (20*40 mil²). In comparison with the wafer susceptor used to carrying thirty-one pieces of the wafers having the diameter of 2 inches, the throughput of the small LED chips is increased by a ratio of about 9.68%, and the throughput of the medium-large LED chips is increased by a ratio of about 9.67%. Moreover, in comparison with the wafer susceptor used to carrying seven pieces of the wafers having the diameter of 4 inches, the throughput of the small LED chips is further increased by a ratio of about 21.43%, and the throughput of the medium-large LED chips is increased by a ratio of about 21.43%.

According to the aforementioned description, it is known that with the same size of the wafer susceptor, the design of wafer pockets having various sizes truly can give consideration to the use of large wafers and the space utilization ratio of the wafer susceptor. Accordingly, by using the wafer susceptors including wafer pockets of various sizes in the aforementioned embodiments, the production efficiency can be effectively enhanced to obtain a superior advantage for mass production.

According to the aforementioned embodiments, one advantage of the present invention is that a wafer susceptor of a MOCVD apparatus is set with wafer pockets of various sizes, so that the use space of the wafer susceptor can be utilized more effectively.

According to the aforementioned embodiments, another advantage of the present invention is that a wafer susceptor of a MOCVD apparatus is designed to have a large carrying space, so that the production efficiency of devices is greatly increased, thereby enhancing the throughput.

According to the aforementioned embodiments, still another advantage of the present invention is that a MOCVD apparatus can give consideration to the space utilization ratio of a wafer susceptor and the use of large wafers, so that the production cost is reduced.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A metal-organic chemical vapor deposition apparatus, including:
a reaction chamber including an opening;
a rotation stand disposed within the reaction chamber;
a wafer susceptor disposed on the rotation stand, wherein the wafer susceptor rotates by rotating of the rotation stand, the wafer susceptor includes a plurality of wafer pockets of at least two different diameters disposed on a surface of the wafer susceptor, and said plurality of wafer pockets are suitable to correspondingly carry a plurality of wafers;
a heater disposed under the wafer susceptor and within the rotation stand; and
a shower head covering the opening of the reaction chamber and applying a gaseous precursor toward the surface of the wafer susceptor.

2. The metal-organic chemical vapor deposition apparatus according to claim 1, wherein the wafer pockets includes a plurality of wafer pockets having a diameter of 2 inches and a plurality of wafer pockets having a diameter of 4 inches.

3. The metal-organic chemical vapor deposition apparatus according to claim 1, wherein the wafer pockets includes a plurality of first wafer pockets having a same diameter and at least one second wafer pocket having a same diameter, and the diameter of the first wafer pockets is longer than the diameter of the at least one second wafer pocket.

4. The metal-organic chemical vapor deposition apparatus according to claim 3, wherein a depth of the first wafer pockets is larger than a depth of the at least one second wafer pocket.

5. The metal-organic chemical vapor deposition apparatus according to claim 3, wherein a depth of the first wafer pockets is the same as a depth of the at least one second wafer pocket.

6. The metal-organic chemical vapor deposition apparatus according to claim 1, wherein a depth of each of the wafer pockets is less than a thickness of the corresponding wafer.

7. The metal-organic chemical vapor deposition apparatus according to claim 1, wherein a depth of each of the wafer pockets is equal to a thickness of the corresponding wafer.

8. The metal-organic chemical vapor deposition apparatus according to claim 1, wherein a shape of each of the wafer pockets is the same as a shape of the corresponding wafer.

9. The metal-organic chemical vapor deposition apparatus according to claim 1, wherein a diameter of each of the wafer pockets is equal to or longer than a diameter of the corresponding wafer.

10. The metal-organic chemical vapor deposition apparatus according to claim 1, wherein the heater will not rotate while the rotation stand is rotating.
